(19) United States
(12) Patent Application Publication
(10) Pub. No.: US 2025/0208242 A1
(43) Pub. Date: Jun. 26, 2025

(54) RECEIVE COIL UNIT AND MAGNETIC RESONANCE IMAGING APPARATUS

(71) Applicant: FUJIFILM Corporation, Tokyo (JP)

(72) Inventors: Takeshi TANIGUCHI, Tokyo (JP); Koichi ARAI, Tokyo (JP); Yosuke OTAKE, Tokyo (JP); Kojiro IWASAWA, Tokyo (JP)

(73) Assignee: FUJIFILM Corporation, Tokyo (JP)

(21) Appl. No.: 19/000,715

(22) Filed: Dec. 24, 2024

(30) Foreign Application Priority Data
Dec. 26, 2023 (JP) 2023-220062

(51) Int. Cl. G01R 33/3415; G01R 33/28; G01R 33/36

(52) U.S. Cl. CPC G01R 33/3415; G01R 33/288; G01R 33/3657

(57) ABSTRACT

Provided are a receive coil unit that can suppress heat transfer from a heat generation element disposed inside a coil cover to a subject and that can release heat generated from the heat generation element or the subject from between the coil cover and the subject, and a magnetic resonance imaging apparatus comprising the receive coil unit. A receive coil unit includes: a coil element that receives a signal generated from a subject; a heat generation element that is connected to the coil element; a coil cover that covers an outside of the coil element and the heat generation element; and buffer members each having a convex shape toward a subject side, the buffer members being disposed at a position overlapping a region of the heat generation element as viewed from the subject side, on a surface of the coil cover that comes into contact with the subject.

### CROSS-REFERENCE TO RELATED APPLICATION

The present application claims priority under 35 U.S.C § 119(a) to Japanese Patent Application No. 2023-220062 filed on Dec. 26, 2023, which is hereby expressly incorporated by reference, in its entirety, into the present application.

### BACKGROUND OF THE INVENTION

### 1. Field of the Invention

The present disclosure relates to a receive coil unit and a magnetic resonance imaging (MRI) apparatus.

### 2. Description of the Related Art

In the MRI apparatus, a subject placed in a static magnetic field is irradiated with high-frequency electromagnetic waves to excite nuclear spins in the subject, such as nuclear spins of hydrogen atoms, and a nuclear magnetic resonance (NMR) signal generated in a case in which the excited nuclear spins return to an equilibrium state is detected and subjected to signal processing, thereby creating an image of a hydrogen nuclei distribution in a living body.

It is desirable that a receive coil that receives the NMR signal from the subject is disposed close to the subject in order to obtain high sensitivity. Therefore, as the receive coil, a coil by use is prepared according to a shape of an imaging target part, such as a head, an abdomen, and limbs.

JP2014-94035A discloses an RF coil unit for children to which an abdominal coil can be attached. In the RF coil unit disclosed in JP2014-94035A, a surface of a support portion in which a coil element is housed and which comes into contact with a subject is formed of a cushion material having unevenness.

JP1998-155764A (JP-H10-155764A) discloses a technique of interposing a buffer member between a subject and a receive coil. JP2012-130701A discloses a coil manufactured in a form of a flexible blanket.

### SUMMARY OF THE INVENTION

A blanket-shaped abdominal receive coil unit has a structure in which a flexible bag-shaped coil cover is used outside internal electrical components to cover the entire electrical components, in order to provide a lighter and more flexible structure than an integrally formed type coil in which internal electrical components such as a coil element and an electric circuit are integrally configured with a coil cover made of a resin or the like. The electrical components housed inside the coil cover include an element that generates heat by being irradiated with energy of a high-frequency electromagnetic wave. Meanwhile, in the blanket-shaped receive coil unit, the coil cover is in close contact with the subject due to the flexibility of the coil cover, so that it is difficult to release heat from the subject, and heat is likely to be trapped.

The technique disclosed in JP2014-94035A aims to release heat generated from an infant whose body temperature regulation is immature, but JP2014-94035A does not take into consideration heat generated from a heat generation element. In addition, even in a case in which the cushion material disclosed in JP2014-94035A is applied to the blanket-shaped receive coil unit, the cushion material is continuously arranged without gaps over the entire surface between the subject and the receive coil unit. Therefore, the cushion material and the subject are continuously in close contact with each other in a plane direction, so that heat is difficult to be released.

The technique disclosed in JP1998-155764A (JP-H10-155764A) also does not take into consideration heat generated from the heat generation element, and since the buffer member is interposed over the entire surface between the subject and the receive coil, there is a problem in that heat is difficult to be released.

The present disclosure has been made in view of such circumstances, and an object of the present disclosure is to provide a receive coil unit that can suppress heat transfer from a heat generation element disposed inside a coil cover to a subject and that can release heat generated from the heat generation element or the subject from between the coil cover and the subject, and a magnetic resonance imaging apparatus comprising the receive coil unit.

A first aspect of the present disclosure provides a receive coil unit comprising: a coil element that receives a signal generated from a subject; a heat generation element that is connected to the coil element; a coil cover that covers an outside of the coil element and the heat generation element; and a plurality of buffer members each having a convex shape toward a subject side, the buffer members being disposed at positions overlapping a region of the heat generation element as viewed from the subject side, on a surface of the coil cover that comes into contact with the subject.

According to the first aspect, the plurality of buffer members are provided on the surface of the coil cover that comes into contact with the subject, and the surface of the coil cover on the subject side has an uneven shape. A recess portion between the buffer members in the uneven shape functions as a passage for air, and in a state in which the receive coil unit is mounted on the subject, heat can be released from between the coil cover and the subject via a ventilation path of the recess portion. In addition, heat generated from the heat generation element disposed inside the coil cover is difficult to be transmitted to the subject according to a heat insulating effect of the air interposed between the coil cover and the subject.

A second aspect provides the receive coil unit according to the first aspect, in which it is preferable that a thickness of the buffer member is 5 mm or less.

A third aspect provides the receive coil unit according to the first or second aspect, in which the buffer member may be fixed to the coil cover by a structure in which the buffer member is attached to the surface of the coil cover.

A fourth aspect provides the receive coil unit according to any one of the first to third aspects, in which the buffer member may be integrally configured with the coil cover.

A fifth aspect provides the receive coil unit according to any one of the first to fourth aspects, in which a plurality of the coil elements and a plurality of the heat generation elements may be provided, and the buffer member may be disposed at a position overlapping a region of each of the plurality of heat generation elements as viewed from the subject side, on the surface of the coil cover.

A sixth aspect provides the receive coil unit according to any one of the first to fifth aspects, in which the coil cover may be a flexible bag-shaped cover that is deformable to fit a physique of the subject.

A seventh aspect provides the receive coil unit according to any one of the first to sixth aspects, in which the buffer member may include air bubbles.

An eighth aspect provides the receive coil unit according to any one of the first to sixth aspects, in which the buffer member may have a hollow structure.

A ninth aspect provides the receive coil unit according to any one of the first to eighth aspects, in which the buffer member may be formed of a heat insulating member.

A tenth aspect provides the receive coil unit according to any one of the first to ninth aspects, in which the buffer member may not be disposed at a center position of the region of the heat generation element on the surface of the coil cover.

A eleventh aspect provides the receive coil unit according to any one of the first to tenth aspects, in which the buffer member may not be disposed in a region separated from the region of the heat generation element by a predetermined distance or more on the surface of the coil cover.

A twelfth aspect provides the receive coil unit according to any one of the first to eleventh aspects, in which the signal received by the coil element may be a nuclear magnetic resonance signal.

A thirteenth aspect provides the receive coil unit according to any one of the first to twelfth aspects, in which the heat generation element may include at least one of an inductor, a capacitor, or a diode.

A fourteenth aspect provides the receive coil unit according to any one of the first to thirteenth aspects, in which the heat generation element may include a resonance circuit for removing coupling between a transmission coil that irradiates the subject with a radio frequency magnetic field and the coil element.

A fifteenth aspect provides a magnetic resonance imaging apparatus comprising: the receive coil unit according to any one of the first to fourteenth aspects, in which a magnetic resonance image is generated from a nuclear magnetic resonance signal received by using the receive coil unit.

According to the present invention, it is possible to suppress heat transfer from a heat generation element disposed inside a coil cover to a subject and to release heat generated from the heat generation element or the subject from between the coil cover and the subject.

### BRIEF DESCRIPTION OF THE DRAWINGS

FIG. 1 is an external perspective view of an MRI apparatus to which a receive coil unit according to an embodiment of the present invention is applied.

FIG. 2 is a schematic diagram showing an internal configuration of an MRI apparatus.

FIG. 3 is an exploded perspective view schematically showing a configuration of the receive coil unit according to the embodiment.

FIG. 4 is a plan view schematically showing another example of an arrangement form of heat generation elements.

FIG. 5 is a circuit diagram showing an example of the heat generation element.

FIG. 6 is a schematic cross-sectional view of the receive coil unit.

FIG. 7 is a perspective view showing an example of a buffer member.

FIG. 8 is an enlarged cross-sectional view of the receive coil unit.

FIG. 9 is a view showing an arrangement example of the buffer members as seen from a direction of an arrow A in FIG. 8.

FIG. 10 is an explanatory view showing an example of a buffer member having a hollow structure.

FIG. 11 is an explanatory view showing an example of a buffer member in which a heat insulating effect of air and a heat convection effect of air are obtained.

### DESCRIPTION OF THE PREFERRED EMBODIMENTS

Hereinafter, a preferred embodiment of the present invention will be described with reference to the accompanying drawings. In the following description and the accompanying drawings, constituent elements having the same functional configuration are denoted by the same reference numerals, and the duplicated description thereof is omitted.

### Description of MRI Apparatus

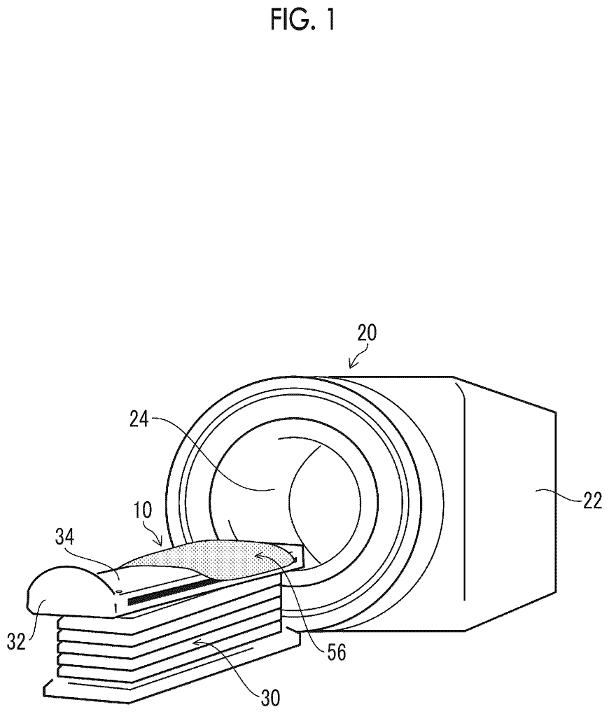

FIG. 1 is an external perspective view of an MRI apparatus 20 to which a receive coil unit 10 according to an embodiment of the present invention is applied. The MRI apparatus 20 comprises a gantry 22 which is an apparatus main body, a bed apparatus 30 on which a subject is placed, and a receive coil unit 10 that receives a signal from the subject.

The gantry 22 is disposed in an electromagnetic-shielded room (examination room or imaging room) of a medical facility such as a hospital. The subject is placed on a top plate 34 of a table 32 of the bed apparatus 30 and is transported toward the gantry 22 by a movement operation of the table 32. The gantry 22 has a bore 24 that is an imaging space, and the table 32 is moved within the bore 24.

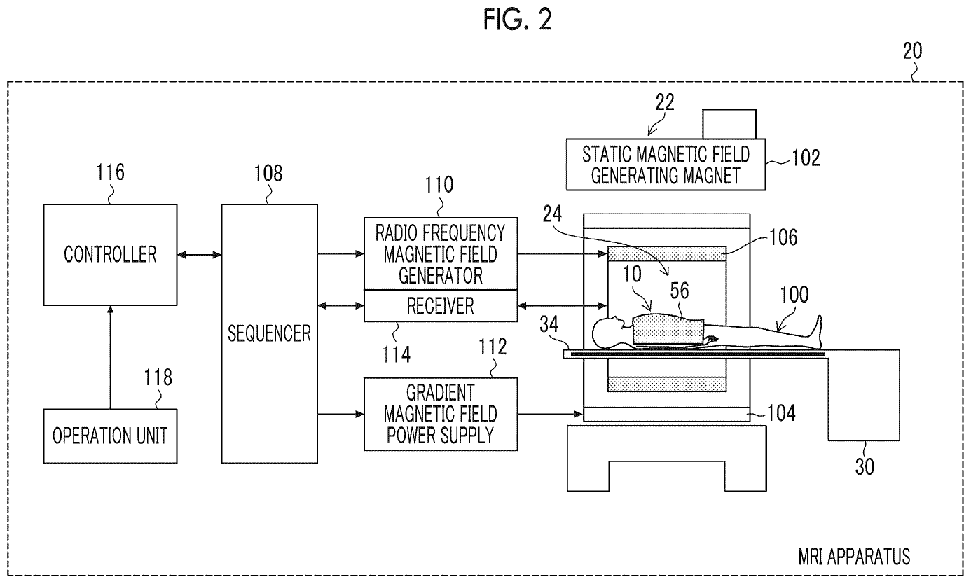

FIG. 2 is a schematic diagram showing an internal configuration of the MRI apparatus 20. The MRI apparatus 20 comprises a static magnetic field generating magnet 102, a gradient magnetic field coil 104, and a transmission coil 106.

The static magnetic field generating magnet 102 generates a uniform static magnetic field in the bore 24. The gradient magnetic field coil 104 generates a gradient magnetic field in the bore 24. The transmission coil 106 is a radio frequency (RF) coil that generates a radio frequency magnetic field for generating a nuclear magnetic resonance (NMR) signal in nucleus of an atom constituting a tissue of a subject 100 disposed in the bore 24.

The receive coil unit 10 is mounted on the subject 100 placed on the top plate 34. By moving the table 32 on which the subject 100 is placed into the bore 24, an examination part (imaging target part) of the subject 100 is positioned at the center of the static magnetic field of the bore 24.

The MRI apparatus 20 further comprises a sequencer 108, a radio frequency magnetic field generator 110, a gradient magnetic field power supply 112, a controller 116, and an operation unit 118. The power supply and control and signal processing systems of the MRI apparatus 20 are disposed outside the electromagnetic-shielded room (for example, a machine room and/or an operation room) and are electrically connected to the gantry 22 via a cable. The sequencer 108 sends commands to a radio frequency magnetic field generator 110 and a gradient magnetic field power supply 112 in accordance with an imaging sequence to generate a radio frequency magnetic field and a gradient magnetic field.

The generated radio frequency magnetic field is applied to the subject 100 as a pulsed radio frequency magnetic field (RF pulse) through the transmission coil 106. The NMR signal generated from the subject 100 is received by the receive coil unit 10, and is demodulated by a receiver 114.

The gradient magnetic field coil 104 is composed of gradient magnetic field coils in three directions of X, Y, and Z, and generates gradient magnetic fields according to the signals from the gradient magnetic field power supply 112.

A nuclear magnetic resonance frequency (demodulation reference frequency f0) to be used as a reference for the demodulation in the receiver 114 is set by the sequencer 108. The sequencer 108 performs control such that each unit operates at pre-programmed timing and intensity. Among programs, a program that particularly describes the timing and intensity of RF pulses, gradient magnetic fields, and signal reception is referred to as a pulse sequence.

Various pulse sequences depending on the purpose are known, but the detailed description thereof will be omitted here.

The controller 116 controls an operation of each unit of the MRI apparatus 20 via the sequencer 108. In addition, the controller 116 receives the signal demodulated by the receiver 114 and performs various types of signal processing such as image reconstruction. The receiver 114 performs quadrature phase demodulation on an echo signal (NMR signal), which is an analog wave, using the set demodulation reference frequency f0, converts the echo signal into raw data, and then transmits the raw data to the controller 116. This raw data is also referred to as an echo signal or measurement data.

The controller 116 receives various instruction inputs from an operation unit 118 and integrally controls respective units of the MRI apparatus 20. In addition, the controller 116 performs processing of performing inverse Fourier transform on the echo signal in a spatial frequency region received via the sequencer 108 to convert the reception signal into an image in a real space, and generates a magnetic resonance image (MRI image).

The controller 116 is implemented by a general-purpose computer such as a personal computer or a microcomputer. The controller 116 comprises a central processing unit (CPU), a read only memory (ROM), a random access memory (RAM), an input/output interface, and the like.

In the controller 116, various programs such as a control program stored in the ROM, the storage, and the like are loaded onto the RAM, and the programs loaded onto the RAM are executed by the CPU. As a result, the functions of the respective units of the MRI apparatus 20 are implemented, and various types of arithmetic processing and control processing are executed via the input/output interface.

The operation unit 118 includes an input device such as a mouse or a keyboard, and functions as a part of a graphical user interface (GUI) that receives an input from an imaging staff by using a display operation window of a display (not shown).

That is, the operation unit 118 functions as a GUI for the imaging staff to input start and stop (including pause) of the MRI apparatus 20, selection of the pulse sequence, an imaging condition, a processing condition, and the like. The operation unit 118 may include a voice input device.

### Description of Receive Coil Unit 10

The receive coil unit 10 is a blanket-shaped abdominal receive coil, and is flexible as a whole so that it can be deformable to fit the physique of the subject 100, and is configured to be thin and lightweight.

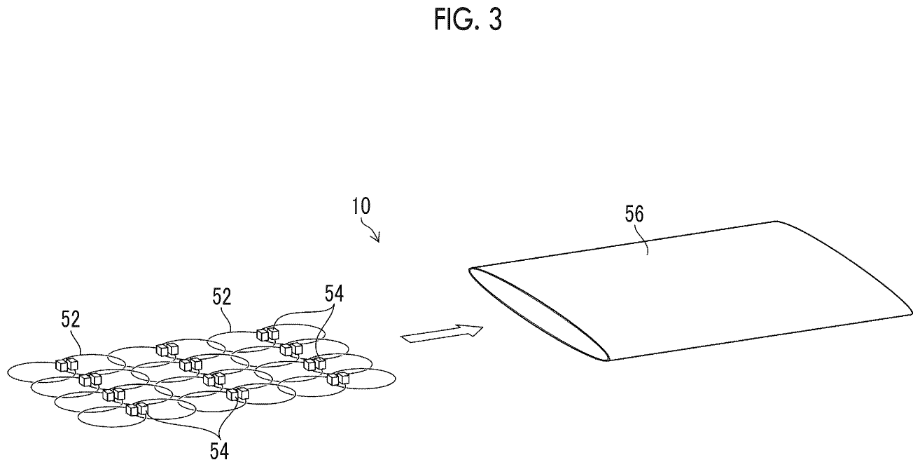

FIG. 3 is an exploded perspective view schematically showing a configuration of the receive coil unit 10 according to the embodiment. The receive coil unit 10 is an array coil in which multi-channelization is achieved, and comprises a plurality of coil elements 52, a plurality of heat generation elements 54 that are electrical components respectively connected to the coil elements 52, and a bag-shaped coil cover 56. The coil elements 52 are sub-coils of the array coil.

Each of the plurality of coil elements 52 functions as an antenna that receives an NMR signal generated from a biological tissue of the subject 100. Each coil element 52 is adjusted to resonate at a specific frequency. The specific frequency is decided by an atomic nucleus (usually, a hydrogen nucleus) to be observed in the biological tissue, and a magnetic field intensity. The coil elements 52 are, for example, ring-shaped with a diameter of about 10 cm to 15 cm or square-shaped with one side of about 10 cm to 15 cm, and are two-dimensionally arranged inside the coil cover 56.

FIG. 3 shows an example in which 24 coil elements 52 are two-dimensionally arranged, but the size, number, and arrangement form of the coil elements 52 are not limited to the example shown in FIG. 3. The number of the coil elements 52 in the abdominal receive coil may be, for example, in a range of 16 to 128.

The heat generation element 54 is connected to each of the plurality of coil elements 52. The heat generation element 54 is an element that generates heat by receiving energy of a radio frequency magnetic field emitted from the transmission coil 106. The heat generation element 54 may be an electric circuit module in which an electric circuit including a plurality of circuit elements is packaged. The heat generation element 54 may be, for example, a molded product having a substantially rectangular parallelepiped outer shape. As an example, the heat generation element 54 may have a three-dimensional shape of which a quadrangular bottom surface has one side of about 2 cm to 3 cm and a height (thickness) is about 2 cm. The shape and size of the heat generation element 54 are not limited to this example, and various forms may be available. The heat generation elements 54 are two-dimensionally arranged inside the coil cover 56 in accordance with the arrangement of the coil elements 52.

The coil cover 56 is a cover that constitutes an exterior body that covering the outside of the plurality of coil elements 52 and the plurality of heat generation elements 54. Electrical components including the plurality of coil elements 52 and the plurality of heat generation elements 54 are housed inside the coil cover 56 to form a blanket-shaped receive coil unit 10. The plurality of coil elements 52 and the plurality of heat generation elements 54 may be housed inside the coil cover 56 in a state of being fixed on a film (not shown). The film is a support member that fixes a positional relationship between the coil element 52 and the heat generation element 54 and suppresses positional deviation.

A cable unit (not shown) is connected to the coil cover 56. The cable unit is a unit in which multi-channel cables for obtaining signals from each of the plurality of coil elements 52 are bundled together.

The form of the two-dimensional arrangement of the plurality of heat generation elements 54 corresponding to the respective coil elements 52 is not limited to the example of the arrangement shown in FIG. 3, and may be appropriately designed.

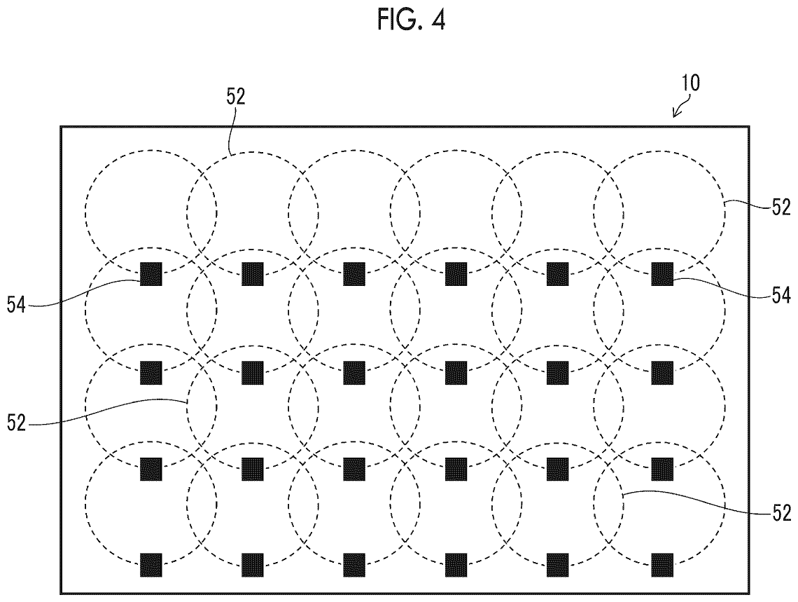

FIG. 4 is a plan view schematically showing another example of the arrangement form of the heat generation elements 54. Instead of the arrangement form of the heat generation elements 54 shown in FIG. 3, for example, as shown in FIG. 4, the plurality of heat generation elements 54 may be arranged at regular intervals (periodically) in the same manner as the arrangement pattern of the coil elements 52. The arrangement form of the heat generation elements 54 is not limited to the arrangement pattern having spatial periodicity, and may be an arrangement pattern not having periodicity.

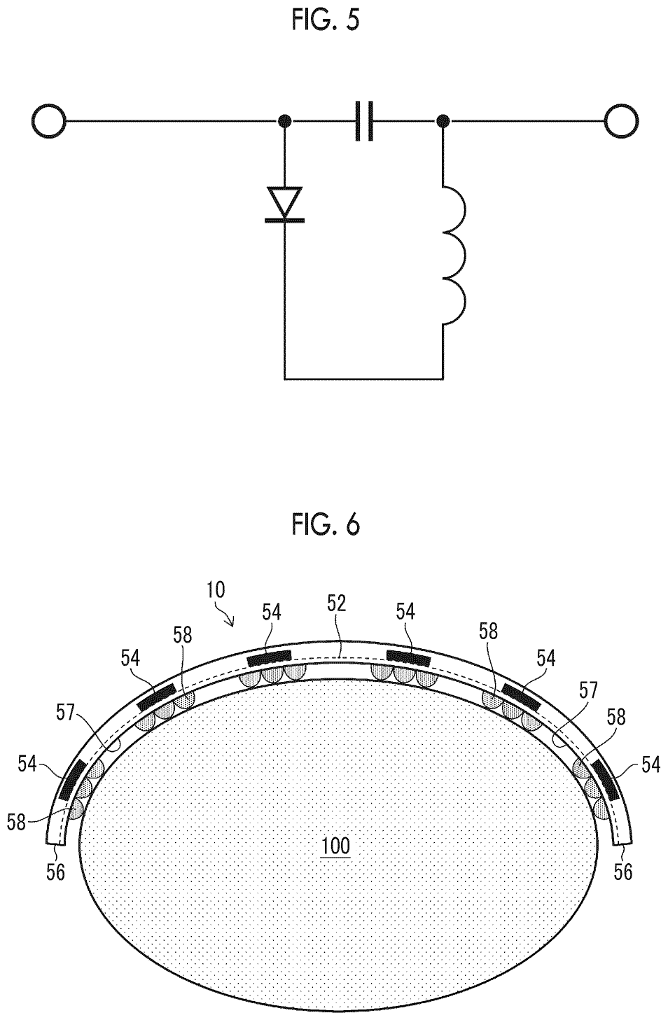

FIG. 5 is a circuit diagram showing an example of the heat generation element 54. In FIG. 5, for convenience of description, an example of an extremely simplified circuit is shown. The heat generation element 54 includes, for example, a resonance circuit for removing the coupling between the coil element 52 and the transmission coil 106 (irradiation coil), that is, a so-called decoupling circuit. As shown in FIG. 5, each of a diode, an inductor, and a capacitor used in the resonance circuit corresponds to a circuit element that generates heat upon receiving RF irradiation energy.

FIG. 6 is a schematic cross-sectional view of the receive coil unit 10. FIG. 6 shows a cross-sectional view of the receive coil unit 10 in a state of being mounted on the abdomen of the subject 100 for MRI imaging. The receive coil unit 10 is provided with a buffer member 58 at a location where the heat generation element 54 is disposed internally, that is, at a position overlapping a region of the internal heat generation element 54 as viewed from the subject 100 side, on a surface of the coil cover 56 that comes into contact with the subject 100 (hereinafter, referred to as a subject contact-side surface 57). In other words, as viewed from the heat generation element 54 side, the buffer member 58 is disposed below the heat generation element 54 at a position overlapping the region of the heat generation element 54 in plan view.

It is preferable that the buffer member 58 is always disposed at a position overlapping the region of each of the plurality of heat generation elements 54 disposed inside the coil cover 56. One or more, more preferably a plurality of the buffer members 58 are disposed at positions overlapping the region of one heat generation element 54. The buffer member 58 may be disposed only in the vicinity of the region of the heat generation element 54, and the buffer member 58 may not be disposed in a region separated from the region of the heat generation element 54 by a predetermined distance or more.

In consideration of a range of positional deviation of the heat generation element 54 in the coil cover 56, the buffer member 58 may be distributed and disposed at a position overlapping the anticipated region such that the buffer member 58 exists at a position overlapping the region of the heat generation element 54 even in a case in which the position of the heat generation element 54 inside the coil cover 56 is slightly deviated from a reference position. The deviation (position error) of the position of the heat generation element 54 with respect to the reference position may be, for example, within 2 cm.

The buffer member 58 has a convex shape toward the subject 100, and the subject contact-side surface 57 of the coil cover 56 has an uneven shape because of the convex shape of the buffer member 58 and the arrangement pattern of the plurality of buffer members 58. That is, a recess portion is formed between the buffer members 58, which are convex portions, and, in a state in which the receive coil unit 10 is mounted on the subject 100, the recess portion serves as a passage for air (ventilation path).

A recess portion between adjacent buffer members 58 of the plurality of buffer members 58 disposed at positions overlapping the region of the same heat generation element 54 and a recess portion which is a buffer member non-disposed region that is separated from the region of the heat generation element 54 by a certain distance or more function as a ventilation path, and heat can be released by air flowing through these recess portions.

A thickness of the buffer member 58 can be appropriately designed, but in a case in which the coil element 52 is too far away from the subject 100 in a state in which the receive coil unit 10 is mounted on the subject 100, the sensitivity of signal detection is lowered, so that it is desirable that the buffer member 58 is not made to have a structure that is larger than necessary. From such a viewpoint, the thickness of the buffer member 58 is desirably 5 mm or less. The thickness of the buffer member 58 may be a maximum height of a convex portion in the uneven shape of the subject contact-side surface 57 of the coil cover 56. In a case in which the buffer member 58 has a thickness of approximately 5 mm, it is possible to form a ventilation path for releasing heat while ensuring the required signal detection sensitivity. Examples of Material and Arrangement Form of Buffer Member

The buffer member 58 is preferably made of a material and/or has a structure that makes it difficult for the heat from the heat generation element 54 to be transmitted to the subject 100. The buffer member 58 is preferably formed of a material that is difficult to deteriorate and deform at a temperature of the heat generated from the heat generation element 54.

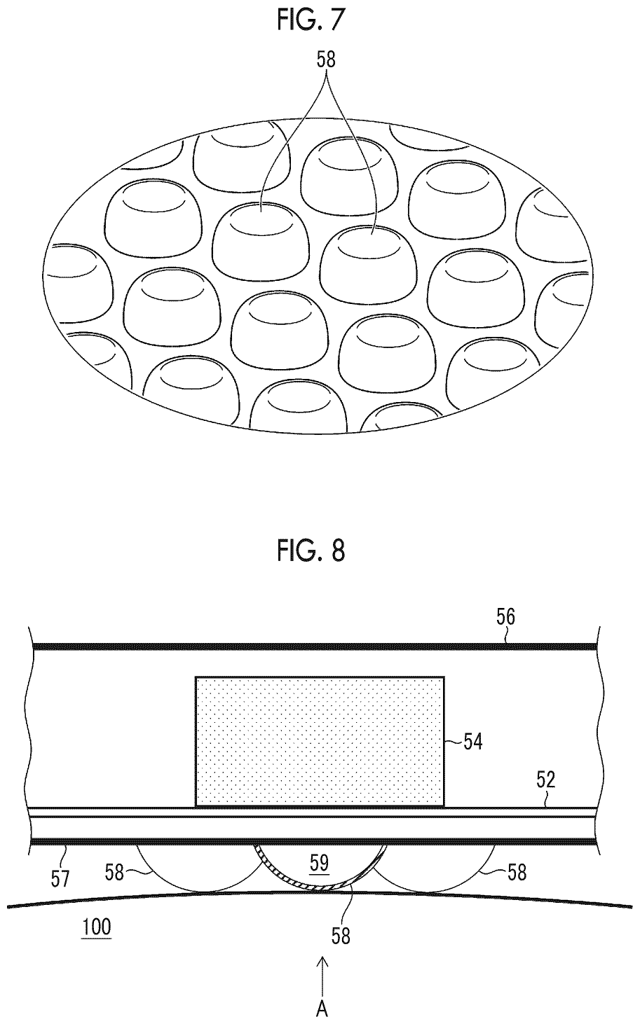

FIG. 7 is a perspective view showing an example of the buffer member 58. The buffer member 58 may be, for example, an air bubble-containing buffer member having granular air bubbles sealed therein, such as an air cap. The buffer member 58 in this case may be formed of, for example, a material containing polyethylene.

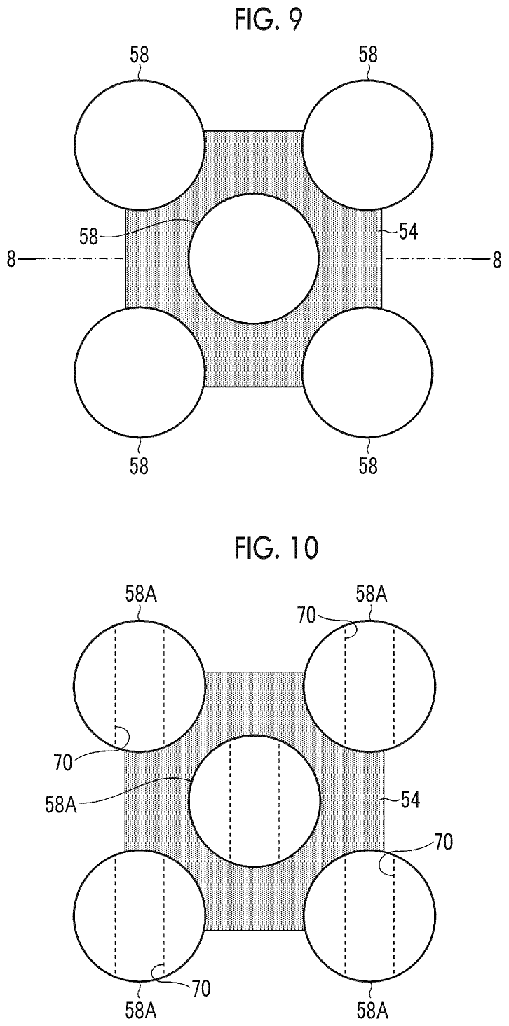

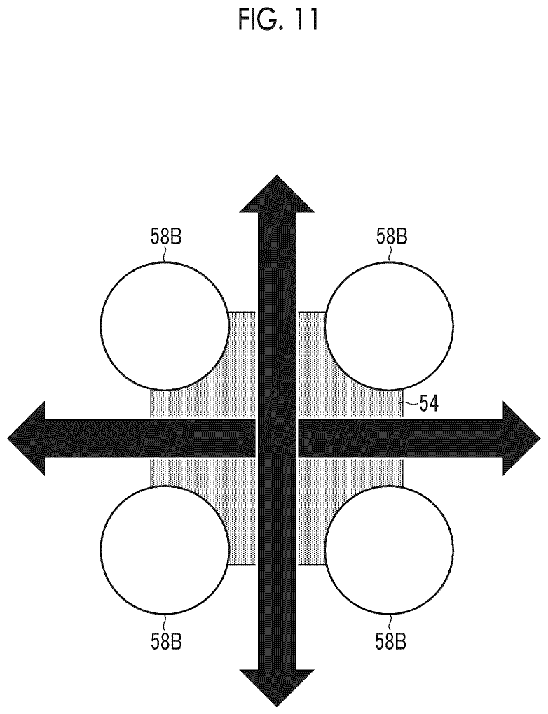

FIG. 8 is an enlarged cross-sectional view of the receive coil unit 10. FIG. 9 is a view (A arrow view) showing an arrangement example of the buffer members 58 as seen from a direction of an arrow A in FIG. 8. In FIG. 9, the coil cover 56 and the coil element 52 are not shown in order to clearly show a positional relationship between the buffer members 58 and the heat generation element 54. The same applies to FIGS. 10 and 11. FIG. 8 shows a cross section taken along line 8-8 of FIG. 9.

As shown in FIG. 8, an antenna pattern in which the coil elements 52 are arranged and the heat generation element 54 are disposed inside the coil cover 56. The buffer member 58 is disposed on the subject contact-side surface 57 of the coil cover 56 between the heat generation element 54 and the subject 100. FIG. 8 shows an example of the buffer member 58 in which air bubble 59 are sealed.

The buffer member 58 has both a heat insulation function of suppressing heat transfer between the heat generation element 54 and the subject 100 and a function as a member that forms a ventilation path for releasing heat. Since the buffer member 58 is provided on the subject contact-side surface 57, the heat generated from the heat generation element 54 is less likely to be transmitted to the subject 100, and the heat can be released from the ventilation path formed between the coil cover 56 and the subject 100.

The buffer members 58 may have a structure in which the convex shapes are isolated (separated) from each other, or may have a structure in which a plurality of the buffer members 58 having a convex shape are fixed on a substrate in an appropriate arrangement pattern. The buffer member 58 may be fixed to the coil cover 56 by a structure in which the buffer member 58 is attached to the subject contact-side surface 57 of the coil cover 56. As a structure for attaching the buffer member 58, for example, a configuration in which double-sided tape, a gluing agent, a hook-and-loop fastener, or the like is used may be adopted. The buffer member 58 that comes into contact with the subject 100 may be worn out over time. By adopting a structure in which the buffer member 58 is attachable to and detachable from the coil cover 56, the worn buffer member 58 can be separated from the coil cover 56 and can be replaced with a new buffer member 58.

Alternatively, the buffer member 58 on the subject contact-side surface 57 may be integrated with the coil cover 56. That is, the coil cover 56 and the buffer member 58 may be configured as a structure in which the coil cover 56 and the buffer member 58 are integrated to be inseparable or difficult to be separated, and the entire coil cover 56 integrated with the buffer member 58 may be replaced with a new coil cover in a case in which the buffer member 58 is worn.

The buffer members 58 are disposed, for example, at positions overlapping the region of the heat generation element 54 as seen from the subject 100 side, as shown in FIG. 9. In a case in which the region of the heat generation element 54 is a rectangular region as shown in FIG. 9, one buffer member 58 may be disposed, for example, at four corners and at the center of the rectangular region. In FIG. 9, an example is shown in which five buffer members 58 are disposed at a distance from each other in the region of one heat generation element 54, but the number and arrangement form of the buffer members 58 disposed at positions overlapping the region of one heat generation element 54 are not limited to the example of FIG. 9. One or more, more preferably a plurality of the buffer members 58 are disposed at positions overlapping the region of one heat generation element 54 in plan view. A distance between the buffer members 58 may be so close that the buffer members 58 are in contact with each other. In addition, the buffer members 58 may be continuously arranged along the sides of the rectangular region of the heat generation element 54.

### Other Form Examples of Buffer Member

Although the buffer member 58 with air bubbles is illustrated in FIGS. 7 and 8, the configuration of the buffer member 58 is not limited to this example. The buffer member 58 may be formed of a material having a low thermal conductivity, for example, a resin material such as a heat insulating member in order to make it difficult for the heat of the heat generation element 54 to be transmitted to the subject 100. As a resin material suitable for the heat insulating member, for example, a foam-based material such as polystyrene foam or urethane foam can be applied. The buffer member 58 may be a porous body having both appropriate hardness and heat insulating properties.

Since heat insulation with air is ideal from the viewpoint of heat transfer suppression and convection can be promoted by forming a passage for air between the subject 100 and the coil cover 56 from the viewpoint of releasing heat, the same effect can be obtained by adopting, for example, a form in which the buffer member 58 has a hollow structure (see FIG. 10) or a form in which the buffer member 58 having a convex shape is formed of hard resin or the like and a passage for air is formed by spacing (thinning out) the buffer members 58 (see FIG. 11).

FIG. 10 is an explanatory view showing an example of a buffer member 58A having a hollow structure. FIG. 10 is a view showing an arrangement example of the buffer members 58A as seen from the direction of the arrow A in FIG. 8, similarly to FIG. 9. A form may be adopted in which the buffer member 58A having a hollow structure with a tunnel-shaped ventilation path 70 as shown in FIG. 10 is provided instead of the buffer member 58 shown in FIGS. 7 and 8.

The ventilation path 70, which is a hollow space that penetrates the buffer member 58A, serves as a passage for air together with a recess portion around the buffer member 58A. In addition, since the ventilation path 70 contains air, the buffer member 58A has a heat insulating effect with air.

In the example of FIG. 10, the ventilation path 70 that penetrates the buffer member 58A is a through-hole that is open at both vertical ends in FIG. 10. However, as shown in FIG. 10, the ventilation paths 70 that penetrate a plurality of the buffer members 58A, respectively, may have a configuration in which both ends of each of the ventilation paths 70 are open in the same direction (vertical direction of FIG. 10), or may have a configuration in which the ventilation paths 70 that are open in different directions are mixed. As shown in FIG. 10, by aligning the direction of the ventilation path 70, a flow of air in that direction is promoted.

The buffer member 58A having a hollow structure may be formed of a resin material such as a heat insulating member or may be formed of a material that is not classified as a heat insulating member.

FIG. 11 is an explanatory view showing an example of a buffer member 58B in which a heat insulating effect of air and a heat convection effect of air are obtained. FIG. 11 is a view showing an arrangement example of the buffer members 58B as seen from the direction of the arrow A in FIG. 8, similarly to FIG. 9. Instead of the buffer member 58 shown in FIGS. 7 and 8, a form of the buffer member 58B as shown in FIG. 11 may be adopted.

The arrangement of the buffer members 58B shown in FIG. 11 is different from the arrangement of the buffer members 58 shown in FIG. 9 in that the buffer member 58B is not disposed at the center position of the rectangular region of the heat generation element 54, and one buffer member 58B is disposed at each of four corners of the rectangular region. The buffer member 58B may be formed of a resin material such as a heat insulating member or may be formed of a material that is not classified as a heat insulating member. The buffer member 58B may be formed of a hard resin or the like.

In comparison with the arrangement of the buffer members 58 and 58A shown in FIGS. 9 and 10, the arrangement of the buffer members 58B shown in FIG. 11 is such that the number of buffer members 58B overlapping the region of the heat generation element 54 is reduced and the region of the recess portion in which the buffer member 58B is not disposed in the region of the heat generation element 54 is large, that is, the ventilation path serving as a passage for air is large. As a result, the transfer of heat from the heat generation element 54 to the subject 100 can be suppressed by the heat insulating effect of the air contained in the space of the recess portion, and convection can be promoted by the large ventilation path, and heat can be released.

### Other Modification Examples

The plurality of buffer members 58 are not limited to the same shape, and different shapes may be mixed, and the heights (thicknesses) of the convex portions may be different.

### Effects of Embodiment

With the receive coil unit 10 according to the embodiment, the following effects can be obtained.

[1] The buffer members 58, 58A, or 58B provided on the subject contact-side surface 57 of the coil cover 56 make the subject contact-side surface 57 uneven, and the space (recess portion) between the buffer members 58 functions as a passage for air. Therefore, due to the heat insulating effect of the air, the heat of the heat generation element 54 is less likely to be transmitted to the subject 100, and the heat generated from the heat generation element 54 and/or the heat generated from the subject 100 can be released from the passage for air between the subject contact-side surface 57 and the subject 100. As a result, the heat sensation of the subject 100 during MRI imaging can be suppressed.

[2] Since the buffer member 58, 58A, or 58B is disposed only in the region near the heat generation element 54 on the subject contact-side surface 57, a contact area with the subject 100 is smaller than that in the form in which the buffer member is disposed on one surface of the subject contact-side surface 57, and a large passage for air, which is a space formed in a non-contact region, can be ensured.

[3] The buffer member 58, 58A, or 58B is replaceable in a case in which the buffer member 58, 58A, or 58B is worn by adopting a structure in which the buffer member 58, 58A, or 58B is attached to the subject contact-side surface 57 of the coil cover 56.

### Others

The present invention is not limited to the range described in the above-described embodiment and modification examples. The configurations and the like in the embodiment and the modification examples can be changed without departing from the spirit of the present invention, and can be appropriately combined between the embodiment and the modification examples.

### EXPLANATION OF REFERENCES

10: receive coil unit
20: MRI apparatus
22: gantry
24: bore
30: bed apparatus
32: table
34: top plate
52: coil element
54: heat generation element
56: coil cover
57: subject contact-side surface
58, 58A, 58B: buffer member
59: air bubble
70: ventilation path
100: subject
102: static magnetic field generating magnet
104: gradient magnetic field coil
106: transmission coil
108: sequencer
110: radio frequency magnetic field generator
112: gradient magnetic field power supply
114: receiver
116: controller
118: operation unit

What is claimed is:

1. A receive coil unit comprising:
a coil element that receives a signal generated from a subject;
a heat generation element that is connected to the coil element;
a coil cover that covers an outside of the coil element and the heat generation element; and
a plurality of buffer members each having a convex shape toward a subject side, the buffer members being disposed at positions overlapping a region of the heat generation element as viewed from the subject side, on a surface of the coil cover that comes into contact with the subject.

2. The receive coil unit according to claim 1,
wherein a thickness of the buffer member is 5 mm or less.

3. The receive coil unit according to claim 1,
wherein the buffer member is fixed to the coil cover by a structure in which the buffer member is attached to the surface of the coil cover.

4. The receive coil unit according to claim 1,
wherein the buffer member is integrally configured with the coil cover.

5. The receive coil unit according to claim 1,
wherein a plurality of the coil elements and a plurality of the heat generation elements are provided, and
the buffer member is disposed at a position overlapping a region of each of the plurality of heat generation elements as viewed from the subject side, on the surface of the coil cover.

6. The receive coil unit according to claim 1,
wherein the coil cover is a flexible bag-shaped cover that is deformable to fit a physique of the subject.

7. The receive coil unit according to claim 1,
wherein the buffer member includes air bubbles.

8. The receive coil unit according to claim 1,
wherein the buffer member has a hollow structure.

9. The receive coil unit according to claim 1,
wherein the buffer member is formed of a heat insulating member.

10. The receive coil unit according to claim 1,
wherein the buffer member is not disposed at a center position of the region of the heat generation element on the surface of the coil cover.

11. The receive coil unit according to claim 1,
wherein the buffer member is not disposed in a region separated from the region of the heat generation element by a predetermined distance or more on the surface of the coil cover.

12. The receive coil unit according to claim 1,
wherein the signal received by the coil element is a nuclear magnetic resonance signal.

13. The receive coil unit according to claim 1,
wherein the heat generation element includes at least one of an inductor, a capacitor, or a diode.

14. The receive coil unit according to claim 1,
wherein the heat generation element includes a resonance circuit for removing coupling between a transmission coil that irradiates the subject with a radio frequency magnetic field and the coil element.

15. A magnetic resonance imaging apparatus comprising:
the receive coil unit according to claim 1,
wherein a magnetic resonance image is generated from a nuclear magnetic resonance signal received by using the receive coil unit.
